(19) United States
(12) Patent Application Publication
(10) Pub. No.: US 2004/0009655 A1
(43) Pub. Date: Jan. 15, 2004

(54) Method for manufacturing metal line contact plugs for semiconductor devices

(76) Inventor: Jong Goo Jung, Gyeonggi-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/603,375

(22) Filed: Jun. 25, 2003

(30) Foreign Application Priority Data
Jul. 15, 2002 (KR) 2002-41145

(51) Int. Cl. H01L 21/4763; H01L 21/302; H01L 21/461

(52) U.S. Cl. 438/622; 438/631; 438/692

(57) ABSTRACT

A method for manufacturing a metal line contact plug of a semiconductor device is disclosed. A stable landing plug poly is formed by etching an interlayer insulating film by using a CMP (chemical mechanical polishing) slurry for an oxide film that includes an alkyl ammonium salt having a high affinity to the oxide film without damaging the hard mask nitride film.

### BACKGROUND

1. Technical Field

Methods for manufacturing metal line contact plugs of semiconductor devices are disclosed. More specifically, the disclosed methods can form a stable landing plug poly (hereinafter, referred to as “LPP”) by etching an interlayer insulating film without damaging a hard mask nitride film. The disclosed methods employ a chemical mechanical polishing (hereinafter, referred to as “CMP”) slurry for an oxide film that includes an alkyl ammonium salt having a high affinity to the oxide film.

2. Description of the Related Art

In order to provide a small, high capacity, and highly integrated semiconductor device, after formation of a transistor, a bitline and a capacitor of a semiconductor device, a multi-line contact, such as a metal line, must be formed which can be electrically connected to each device, ie. the transistor, bitline and capacitor.

However, conventional processes of forming multi-lines using deposition and etching processes does not provide a sufficient process margin for performing subsequent processes. As a result, the subsequent processes become unstable.

Conventionally, silicon layer for an LPP is deposited on a contact hole to form the bitline and the capacitor. The planarization process is performed until an interlayer insulating film is exposed using a conventional slurry for an oxide film. As a result, the silicon layer and the interlayer insulating film in the cell and peri regions are both polished.

However, since the interlayer insulating film has a larger polishing selectivity than that of the silicon layer, the interlayer insulating film of the peri region with a high step difference is excessively polished. Moreover, since an oxide film has a polishing rate similar to that of a nitride film, a hard mask film on a lower portion of the interlayer insulating film is also polished.

As a result, an upper portion of a wordline pattern is exposed, and the process margin such as fine circuit space is lacking. Thus, it is difficult to perform any subsequent processes.

Hereinafter, conventional methods for manufacturing metal line contact plugs of semiconductor devices will be explained with reference to the accompanying drawings.

Referring to FIG. 1A, a process of forming a LPP is observed through a cross section A-A′ of a conventional wordline pattern 4.

Referring to FIG. 1B, a conductive layer (not shown) for a wordline is deposited on a silicon substrate 1. A hard mask film (nitride film) is deposited with a thickness t1 ranging from 1500 to 3200 Å thereon. Then, a wordline pattern 4 where a hard mask pattern 3 is formed on a conductive pattern 2 for a wordline is formed by sequentially etching the resultant surface.

A spacer 5 is formed on the entire pattern 4 as shown. An interlayer insulating film 7 is formed with a thickness t2 ranging from 5000 to 8000 Å on the resultant surface.

Referring to FIG. 1C, the thickness of the interlayer insulating film 7 decreases as it is planarized from the initial thickness t2 to the thickness t4 ranging from 4500 to 7500 Å (t2>t4).

An etching process of forming a contact hole 8 for a plug is performed on a predetermined region of the cell region using a landing plug contact mask (not shown). Here, since an upper portion of the hard mask pattern 3 is also etched, the thickness of the hard mask pattern is decreased from the initial thickness t1 to a thickness t3 ranging from 1000 to 2500 Å (t1>t3).

Referring to FIG. 1D, the region (a) where the contact hole 8 for plug is not formed and the region (b) where the interlayer insulating film is removed to form the contact hole 8 are generated. These regions are observed through a cross section B-B′.

Referring to FIG. 1E, a silicon layer 9 is deposited on the resultant surface including the contact hole 8 (see FIG. 1C) for a plug 11. Here, the silicon layer 9 has a subsequent the step difference of t5 ranging from 1000 to 2000 Å due to the step difference of the regions (a) and (b).

Thereafter, the plug 11 is isolated in a subsequent polishing process. Here, the thickness to be removed is preferably larger than t6 ranging from 2200 to 3200 Å.

Referring to FIG. 1F, a CMP process is performed on the silicon layer 9 using a common slurry for oxide film until the interlayer insulating film 7 is exposed. As a result, the plug 11 is formed.

Referring to FIG. 1G, a CMP process is performed on the silicon layer 9 and the interlayer insulating film 7 using a common slurry for oxide film until the hard mask pattern 3 is exposed. As a result, the plug 11 is isolated.

The slurry for oxide film used in the above CMP process is a common CMP slurry for oxide film with a pH in the range of 2 to 12 and including an abrasive such as colloidal or fumed SiO₂ or Al₂O₃.

Since only the interlayer insulating film 7 having a high polishing selectivity to the slurry for an oxide film is formed on the peri region having high step difference without the silicon layer 9, the interlayer insulating film 9 is easily polished with the CMP process. As a result, the hard mask pattern 3 on a lower region of the interlayer insulating film having no difference in polishing selectivity is also easily polished to expose an upper portion of the wordline pattern 4.

Therefore, in a subsequent process, a misalignment occurs, and a bridge is formed between a wordline and a storage node contact (SNC), thereby increasing leakage current. As a result, the yield of the manufacturing process for such semiconductor devices decreases.

### SUMMARY OF THE DISCLOSURE

Accordingly, a method for forming a stable metal line contact plug using CMP slurry for an oxide film including an additive having a high affinity to an oxide film is disclosed.

### BRIEF DESCRIPTION OF THE DRAWINGS

FIGS. 1A through 1G schematically illustrate a conventional method for manufacturing a semiconductor device via a CMP process.

FIGS. 2A through 2F schematically illustrate a disclosed method for manufacturing a semiconductor device via a CMP process using a disclosed slurry.

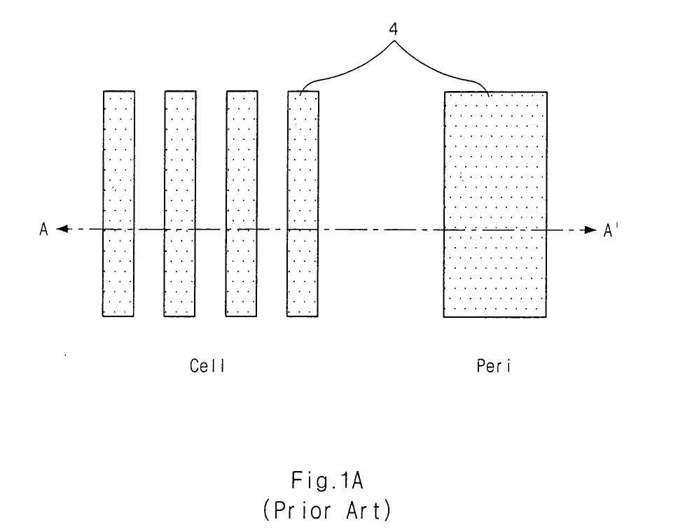

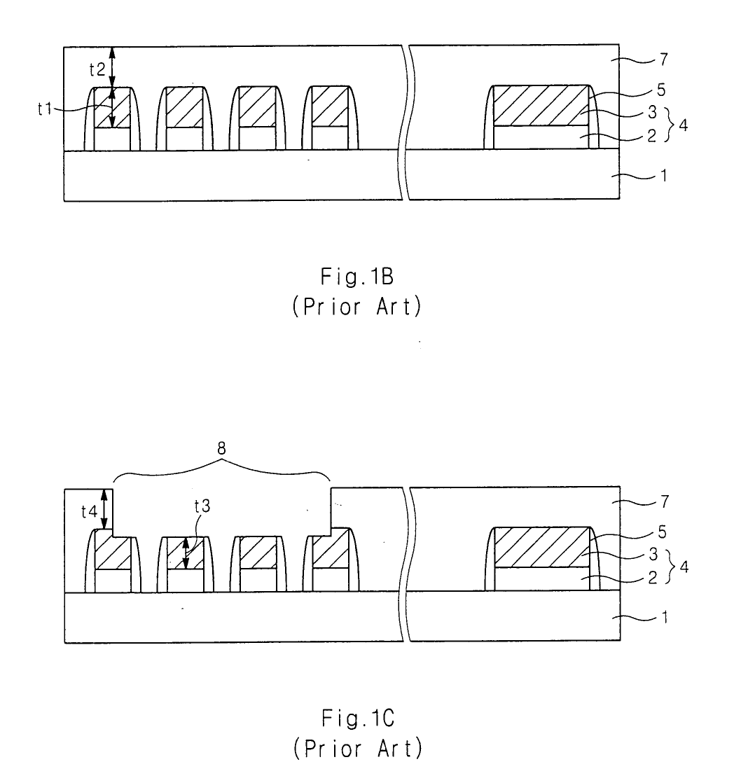

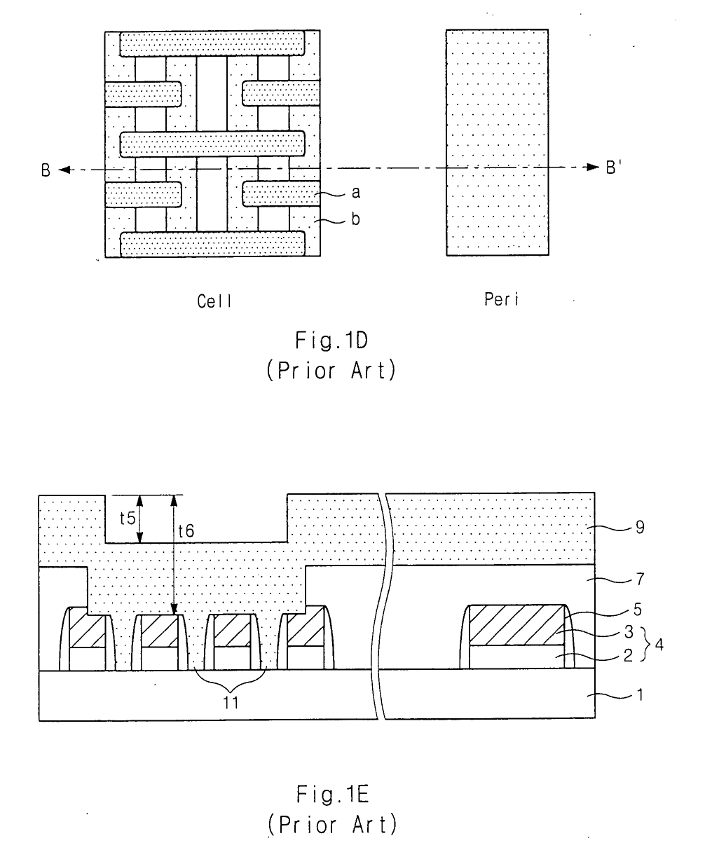

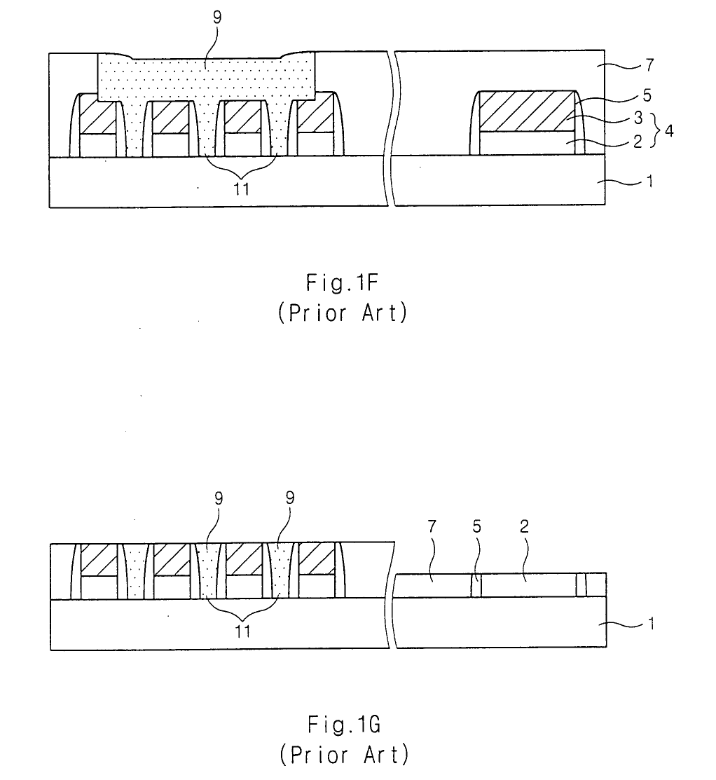

### DETAILED DESCRIPTION OF THE PRESENTLY PREFERRED EMBODIMENTS

A method for manufacturing a metal line contact plug of a semiconductor device is disclosed.

A method for manufacturing a metal line contact plug of a semiconductor device comprises:

depositing a conductive material for a wordline on a semiconductor substrate;

forming a wordline pattern by depositing a hard mask nitride film on an overlapping portion of the conductive material for the wordline;

forming a nitride spacer on a sidewall of the wordline pattern;

forming a planarized interlayer insulating film on the upper portion of the wordline pattern;

forming a contact hole by etching the interlayer insulating film when the substrate is exposed;

forming a silicon layer on the surface of the interlayer insulating film where the contact hole is formed on;

performing a primary CMP process on the silicon layer using a first slurry for an oxide film until the interlayer insulating film is exposed; and

performing a secondary CMP process on the silicon layer and the interlayer insulating film using a second CMP slurry for an oxide film including a solvent, an abrasive dispersed in the solvent and an alkyl ammonium salt (R₍₄₋ₙ₎HₙN⁺X⁻ wherein, n is an integer ranging from 0 to 3) having a high affinity to the oxide film until the hard mask nitride film is exposed.

The alkyl ammonium salt (R₍₄₋ₙ₎HₙN⁺X⁻) has a high affinity to an oxide film because the R may be a linear or branched C₁₀-C₅₀ alkyl, preferably, linear or branched C₁₀-C₂₀ alkyl. Here, the R also may include an unsaturated alkyl group having at least one or more of double bond or triple bond.

In addition, X⁻, an anion, of the alkyl ammonium salt is selected from the group consisting of halogen ions such as F⁻, Cl⁻, Br⁻, I⁻, and complex ions such as CO₃²⁻, PO₄³⁻ and SO₄²⁻.

The alkyl ammonium salt is selected from the group consisting of cetyltrimethylammonium chloride, dodecylethyldimethylammonium bromide, oleyltriethylammonium bromide and didecyldimethylammonium phosphate, and more preferably cetyltrimethylammonium chloride.

The alkyl ammonium salt is present in an amount ranging from 0.01 to 10 wt %, preferably, from 0.01 to 1 wt % based on the CMP slurry.

The above alkyl ammonium salt has a cation characteristic, and therefore the salt interacts with interlayer insulating film having anion characteristic in the peri region having a high step difference during CMP process for isolating a plug in a cell region. In other words, the cation-anion interaction occurs between the alkyl ammonium salt and the interlayer insulating film formed of the oxide film, thereby preventing the interlayer insulating film from contacting with a polishing pad.

As a result, since the polishing speed of the interlayer insulating film decreases, the hard mask pattern remains in the peri region after the polishing process for isolating the plug, and the upper portion of the wordline pattern is not exposed. Therefore, a stable subsequent process can be performed.

Distilled water or ultra pure water is used for the solvent included in the disclosed second slurry for an oxide film.

The abrasive includes Al₂O₃, or colloidal or fumed SiO₂ having a particle size ranging from 50 to 300 nm. Here, the Al₂O₃ is preferably present in an amount ranging from 10 to 30 wt % based on the CMP slurry, and SiO₂ preferably present in an amount ranging from 1 to 2 wt % based on the CMP slurry.

An acidic slurry having a pH ranging from 2 to 7 or a basic slurry having a pH ranging from 8 to 12 can be used for the disclosed second slurry for an oxide film.

The disclosed manufacturing method will be described in detail with reference to the accompanying drawings.

Referring to 2A, a conductive material (not shown) for a wordline is deposited on a silicon substrate 111. A hard mask layer (not shown) is deposited at a thickness t7 ranging from 1500 to 3000 Å thereon using a nitride film. A wordline pattern 114 having a hard mask pattern 113 on a conductive pattern 112 for a wordline is formed by sequentially etching the resultant surface.

Here, the conductive material for wordline is preferably selected from the group consisting of doped silicon, poly-silicon, tungsten (W), tungsten nitrdie (WN), tungsten silicide (WSi_{X}) and titanium silicide (TiSi_{X}).

Thereafter, the wordline pattern 114 is formed via a plasma etching process using a chlorine gas such as CCl₄ or Cl₂ as a source having a high selectivity to a gate oxide film.

Next, TEOS (Tetraethoxysilicate glass) or silane (SiH₄)-based oxide film is deposied via a Low-Pressure chemical vapour deposition (LP CVD), and blanket-etched. As a result, an oxide film spacer 115 is formed on a sidewall of the wordline pattern 114.

An oxide film is deposited at a thickness t8 ranging from 5000 to 8000 Å on the resultant surface using a source selected from the group consisting of BPSG (borophosphosilicate glass), PSG (phosphosilicate glass), FSG (fluorosilicate glass), PE-TEOS (plasma enhanced tetraethoxysilicate glass), PE-SiH₄ (plasma enhanced-silane), HDP USG (high density plasma undoped silicate glass), HDP PSG (high density plasma phosphosilicate glass) and APL (atomic planarization layer) oxide. As a result, an interlayer insulating film 117 is formed, and planarized for a subsequent process.

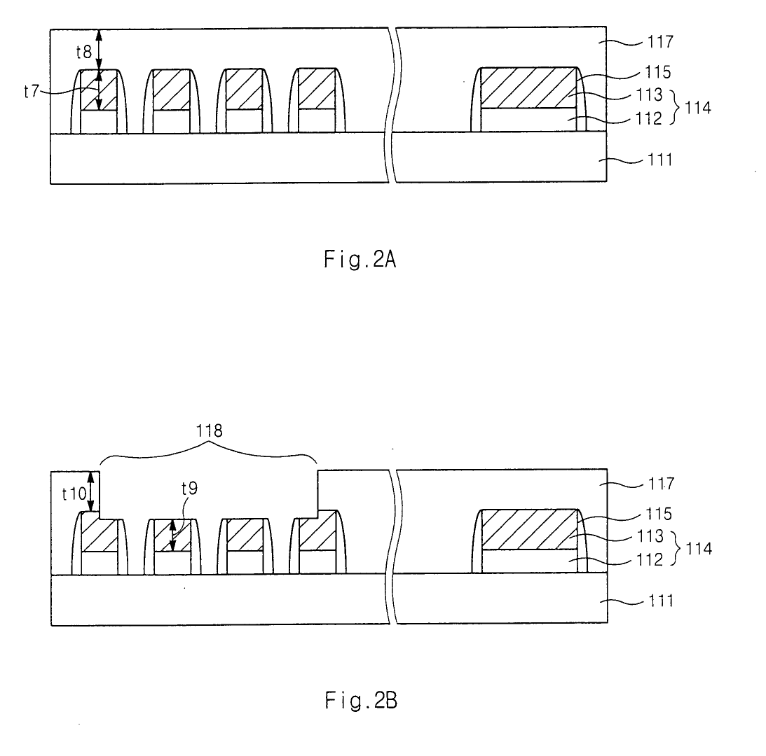

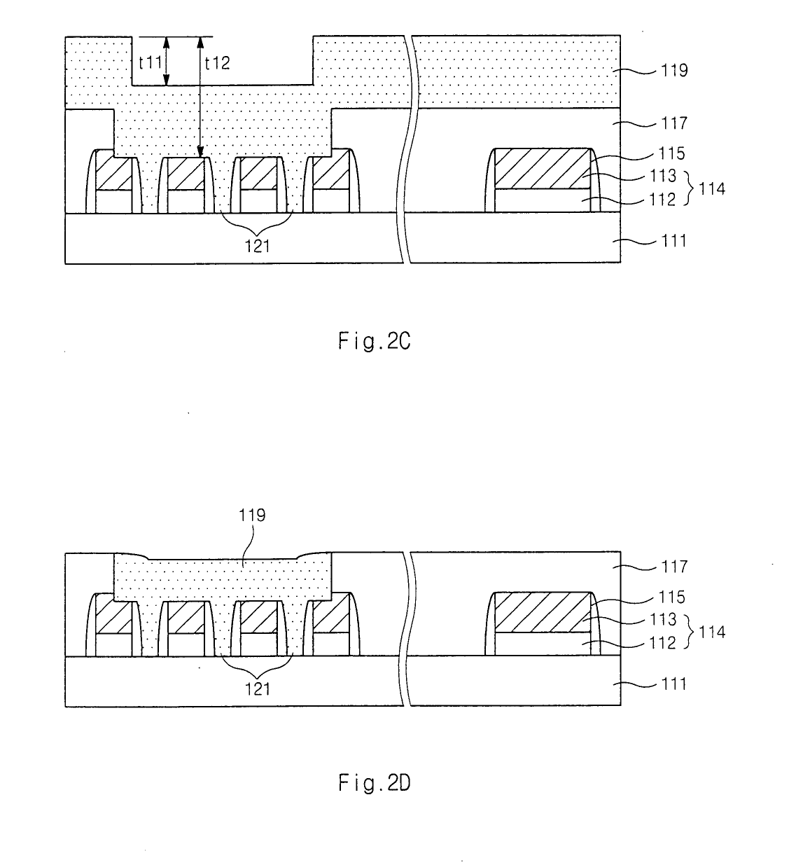

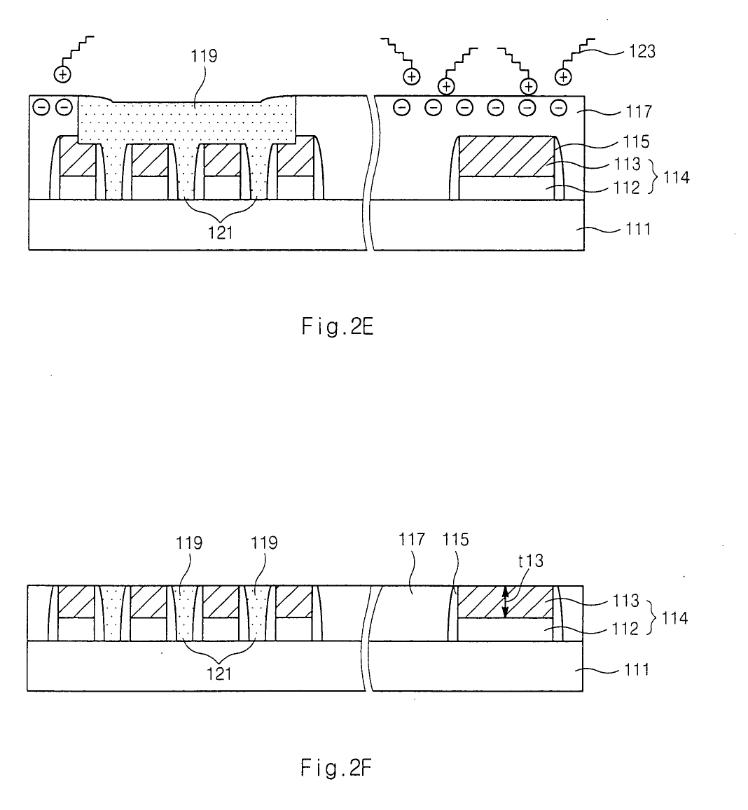

Referring to FIG. 2B, the thickness of the interlayer insulating film 117 decreases from t8 to t10 ranging from 4500 to 7500 Å (t8>t10) via the planarization process.

An etching process is performed on a predetermined portion of a cell region to form a contact hole 118 for a plug using a landing plug contact mask (not shown). Here, since the upper portion of the hard mask pattern 113 is also etched, the thickness of the hard mask pattern 113 decreases from the initial thickness t7 to t9 ranging from 1000 to 2500 Å (t7>t9).

The etching process is a self-aligned contact (SAC) process using a C₄F₈, C₂F₆ or C₃F₈, preferably C₄F₈ source having a high selectivity to the nitride film.

Referring to FIG. 2C, a silicon layer 119 is deposited on the resultant surface including the contact hole 118 for plug. Here, the silicon layer 119 also has step difference by t11 ranging from 1000 to 2000 Å due to the step difference between a region where a contact hole is not formed and a region where an interlayer insulating film is removed to form a contact hole.

The silicon layer is preferably formed of doped silicon or poly-silicon using a SiH₄ or Si₂H₆ source.

Then, a plug 121 is isolated in a subsequent polishing process. Here, the thickness to be removed is preferably larger than t12 ranging from 2200 to 3200 Å.

Referring to FIG. 2D, a primary CMP process is performed to remove the silicon layer 119 on the interlayer insulating film 117 using a common first slurry for an oxide film until the interlayer insulating film 117 is exposed. As a result, the plug 121 is formed.

The common first slurry for an oxide film is a general CMP slurry for an oxide film with a pH in the range 2 to 12 including an abrasive such as colloidal or fumed SiO₂ or Al₂O₃.

Referring to FIG. 2E, a secondary CMP process is performed on the silicon layer 119 and the interlayer insulating film 117 using the disclosed second slurry containing the alkyl ammonium salt until the nitride film hard mask pattern 113 is exposed. As a result, the plug 121 is isolated.

Here, a hard pad is preferably used for a polishing pad. The CMP process is performed under a polishing pressure ranging from 2 to 6 psi and at a table revolution ranging from 10 to 700 rpm.

Here the table revolution is changed according to the operation of CMP equipment. For example, in the case of a rotary type operation, the CMP process is preferably performed at a table revolution ranging from 10 to 200 rpm, and in the case of orbital type operation, the CMP process is preferably performed at a table revolution ranging from 100 to 700 rpm.

Additionally, in the case of linear type operation, the CMP process is preferably performed at a table speed ranging from 100 to 700 fpm (feet per minute).

Referring to FIG. 2F, since the hard mask pattern 113 having a thickness t13 ranging from 1000 to 2000 Å remains after the plug is formed, a stable subsequent process can be performed.

The disclosed method will be described in more detail by referring to examples below, which are not intended to be limiting.

### PREPARATION EXAMPLE 1

To a 99 wt % common slurry for an oxide film including a 20 wt % colloidal SiO₂ as an abrasive was added 1 wt % cetyltrimethylammonium chloride with stirring. Then, the mixture was further stirred for about 30 minutes until the mixture was completely mixed and stabilized. As a result, a disclosed slurry for an oxide film including an additive having a high affinity to an oxide film was prepared.

### PREPARATION EXAMPLE 2

To a 99 wt % common slurry for an oxide film including a 20 wt % fumed SiO₂ as an abrasive was added 2 wt % oleyltriethylammonium bromide with stirring, and 8 wt % ionized water was mixed. Then, the mixture was further stirred for about 30 minutes until the mixture was completely mixed and stabilized. As a result, a disclosed slurry for an oxide film including an additive having a high affinity to an oxide film was prepared.

### PREPARATION EXAMPLE 3

To a 90 wt % common slurry for an oxide film including a 10 wt % Al₂O₃ as an abrasive was added 5 wt % didecyldimethylammonium phosphate with stirring, and 5 wt % ionized water was mixed. Then, the mixture was further stirred for about 30 minutes until the mixture was completely mixed and stabilized. As a result, a disclosed slurry for an oxide film including an additive having a high affinity to an oxide film was prepared.

### EXAMPLE 1

Polishing Process Using the Disclosed Slurry

A silicon layer is deposited on the surface of interlayer insulating film including the contact hole for plug. Then, a primary CMP process is performed to remove the silicon layer on the interlayer insulating film using a common first slurry for an oxide film until the interlayer insulating film is exposed.

A secondary CMP process was performed on an interlayer insulating film by CMP equipment of rotary-type operation under a polishing pressure of 4 psi and at a table revolution of 80 rpm using the disclosed slurry obtained from the preparation example 1.

Since a nitride hard mask having a thickness ranging from 1000 to 2000 Å on a wordline of the peri region remains after the secondary CMP process, a stable metal line contact plug could be formed in a subsequent process.

### EXAMPLE 2

Polishing Process Using the Disclosed Slurry

A silicon layer is deposited on the surface of interlayer insulating film including the contact hole for plug. Then, a primary CMP process is performed to remove the silicon layer on the interlayer insulating film using a common first slurry for an oxide film until the interlayer insulating film is exposed.

A secondary CMP process was performed on an interlayer insulating film by CMP equipment of orbital-type operation under a polishing pressure of 4 psi and at a table revolution of 500 rpm using the disclosed slurry obtained from the preparation example 2.

Since a nitride hard mask having a thickness ranging from 1000 to 2000 Å on a wordline of a peri region remains after the secondary CMP process, a stable metal line contact plug could be formed in a subsequent process.

### EXAMPLE 3

Polishing Process Using the Disclosed Slurry

A silicon layer is deposited on the surface of interlayer insulating film including the contact hole for plug. Then, a primary CMP process is performed to remove the silicon layer on the interlayer insulating film using a common first slurry for an oxide film until the interlayer insulating film is exposed.

A secondary CMP process was performed on an interlayer insulating film by CMP equipment of linear-type operation under a polishing pressure of 4 psi and at a table speed of 600 fpm using the disclosed slurry obtained from the preparation example 3.

Since a nitride hard mask having a thickness ranging from 1000 to 2000 Å on a wordline of a peri region remains after the secondary CMP process, a stable metal line contact plug could be formed in a subsequent process.

As discussed earlier, according to the disclosed method, exposure of the wordline electrode line in the peri region can be prevented, and misalignment can decrease in subsequent processes. Additionally, leakage current cannot be generated by preventing a bridge generated between a wordline and a SNC, thereby improving the manufacturing yield of the devices.

What is claimed is:

1. A method for manufacturing a metal line contact plug of a semiconductor device, the method comprising:
depositing a conductive material for a wordline on a semiconductor substrate;
forming a wordline pattern by depositing a hard mask nitride film on an overlapping portion of the conductive material for the wordline;
forming a nitride spacer on a sidewall of the wordline pattern;
forming a planarized interlayer insulating film on the upper portion of the wordline pattern;
forming a contact hole by etching the interlayer insulating film when the substrate is exposed;
forming a silicon layer on the surface of the interlayer insulating film where the contact hole is formed on;
performing a primary CMP process on the silicon layer using a first slurry for an oxide film until the interlayer insulating film is exposed; and
performing a secondary CMP process on the silicon layer and the interlayer insulating film using a second CMP slurry for an oxide film including a solvent, an abrasive dispersed in the solvent and an alkyl ammonium salt (R₍₄₋ₙ₎HₙN⁺X⁻ wherin, n is an integer ranging from 0 to 3) having a high affinity to the oxide film until the hard mask nitride film is exposed.

2. The method according to claim 1, wherein R of the alkyl ammonium salt is selected from the group consisting of linear C₁₀-C₅₀ alkyl and branched C₁₀-C₅₀ alkyl.

3. The method according to claim 2, wherein R is selected from the group consisting of linear C₁₀-C₂₀ alkyl and branched C₁₀-C₂₀ alkyl.

4. The method according to claim 1, wherein the R includes an unsaturated alkyl group having at least one or more of double bond or triple bond.

5. The method according to claim 1, wherein X— of the alkyl ammonium salt is selected from the group consisting of F⁻, Cl⁻, Br⁻, I⁻, CO₃²⁻, PO₄³⁻and SO₄²⁻.

6. The method according to claim 1, wherein the alkyl ammonium salt is selected from the group consisting of cetyltrimethylammonium chloride, dodecylethyldimethylammonium bromide, oleyltriethylammonium bromide and didecyldimethylammonium phosphate.

7. The method according to claim 1, wherein the alkyl ammonium salt is present in an amount ranging from 0.01 to 10 wt % based on the CMP slurry.

8. The method according to claim 7, wherein the alkyl ammonium salt is present in an amount ranging from 0.01 to 1 wt % based on the CMP slurry.

9. The method according to claim 1, wherein the abrasive is a colloidal or fumed SiO₂ having a particle size ranging from 50 to 300 nm.

10. The method according to claim 1, wherein the abrasive is Al₂O₃.

11. The method according to claim 1, wherein the second slurry for an oxide film has a pH ranging from 2 to 7.

12. The method according to claim 1, wherein the second slurry for an oxide film has an pH ranging from 8 to 12.

13. The method according to claim 1, wherein the conductive material is selected from the group consisting of doped silicon, poly-silicon, tungsten (W), tungsten nitrdie (WN), tungsten silicide (WSi_{X}) and titanium silicide (TiSi_{X}).

14. The method according to claim 1, wherein the wordline pattern is formed by an etching process using CCl₄ or Cl₂ gas.

15. The method according to claim 1, wherein the spacer is formed of TEOS (Tetraethoxysilicate glass) or silane (SiH₄)-based oxide film.

16. The method according to claim 1, wherein the interlayer insulating film is selected from the group consisting of BPSG (borophosphosilicate glass), PSG (phosphosilicate glass), FSG (fluorosilicate glass), PE-TEOS (plasma enhanced tetraethoxysilicate glass), PE-SiH₄ (plasma enhanced-silane), HDP USG (high density plasma undoped silicate glass), HDP PSG (high density plasma phosphosilicate glass) and APL (atomic planarization layer) oxide.

17. The method according to claim 1, wherein the contact hole is formed by an etching process using a C₄F₈, C₂F₆ or C₃F₈ source.

18. The method according to claim 1, wherein the silicon layer is formed of doped silicon or poly-silicon using a SiH₄ or Si₂H₆ source.

19. The method according to claim 1, wherein the CMP process is performed using a hard pad.
